(19) United States
(12) Patent Application Publication
(10) Pub. No.: US 2019/0189943 A1
(43) Pub. Date: Jun. 20, 2019

(54) PHOTOELECTRIC CONVERSION ELEMENT AND METHOD FOR MANUFACTURING PHOTOELECTRIC CONVERSION ELEMENT

(71) Applicant: Kabushiki Kaisha Toshiba, Tokyo (JP)

(72) Inventors: Takeshi GOTANDA, Yokohama (JP); Kenji TODORI, Yokohama (JP)

(73) Assignee: Kabushiki Kaisha Toshiba, Tokyo (JP)

(21) Appl. No.: 16/282,855

(22) Filed: Feb. 22, 2019

Related U.S. Application Data
(62) Division of application No. 15/058,578, filed on Mar. 2, 2016.

(30) Foreign Application Priority Data
Mar. 3, 2015 (JP) 2015-041092

(51) Int. Cl. H01L 51/42; H01L 51/44

(52) U.S. Cl. CPC H01L 51/4213; H01L 51/0037; H01L 51/441; H01L 51/424

(57) ABSTRACT

According to one embodiment, a photoelectric conversion element includes a photoelectric conversion layer, a first electrode, and a first layer. The photoelectric conversion layer includes a material having a perovskite structure. The first electrode includes polyethylene dioxythiophene. The first layer is provided between the photoelectric conversion layer and the first electrode. The first layer has hole transport properties. The hygroscopicity of the first layer is lower than a hygroscopicity of the photoelectric conversion layer.

### CROSS-REFERENCE TO RELATED APPLICATIONS

This application is a divisional of U.S. application Ser. No. 15/058,578, filed on Mar. 2, 2016, based upon and claims the benefit of priority from Japanese Patent Application No. 2015-041092, filed on Mar. 3, 2015; the entire contents of which are incorporated herein by reference.

### FIELD

An embodiment of the invention generally relates to a photoelectric conversion element and a method for manufacturing the photoelectric conversion element.

### BACKGROUND

Research has been made on photoelectric conversion elements such as solar cells and sensors using organic photoelectric conversion materials or photoelectric conversion materials including organic matter and inorganic matter. Devices may be manufactured at relatively low cost when photoelectric conversion elements are produced by printing or coating photoelectric conversion materials. It is desirable to improve the stability of characteristics such as conversion efficiency for such photoelectric conversion elements.

### BRIEF DESCRIPTION OF THE DRAWINGS

FIG. 1A to FIG. 1C are schematic views showing a photoelectric conversion element according to the embodiment;

FIG. 2 is a photograph showing the photoelectric conversion element of the reference example; and

FIG. 3 is a flowchart showing the method for manufacturing the photoelectric conversion element according to the second embodiment.

### DETAILED DESCRIPTION

According to one embodiment, a photoelectric conversion element includes a photoelectric conversion layer, a first electrode, and a first layer. The photoelectric conversion layer includes a material having a perovskite structure. The first electrode includes polyethylene dioxythiophene. The first layer is provided between the photoelectric conversion layer and the first electrode. The first layer has hole transport properties. The hygroscopicity of the first layer is lower than a hygroscopicity of the photoelectric conversion layer.

According to one embodiment, a method for manufacturing a photoelectric conversion element is provided. The element includes a photoelectric conversion layer, a first electrode, and a first layer. The photoelectric conversion layer includes a material having a perovskite structure. The first electrode includes polyethylene dioxythiophene. The first layer is provided between the photoelectric conversion layer and the first electrode. The first layer has hole transport properties. The hygroscopicity of the first layer is lower than a hygroscopicity of the photoelectric conversion layer. The method includes forming the first layer by coating a coating liquid on the photoelectric conversion layer. The method includes forming the first electrode by coating an ethanol aqueous solution including a first material on the first layer.

### First Embodiment

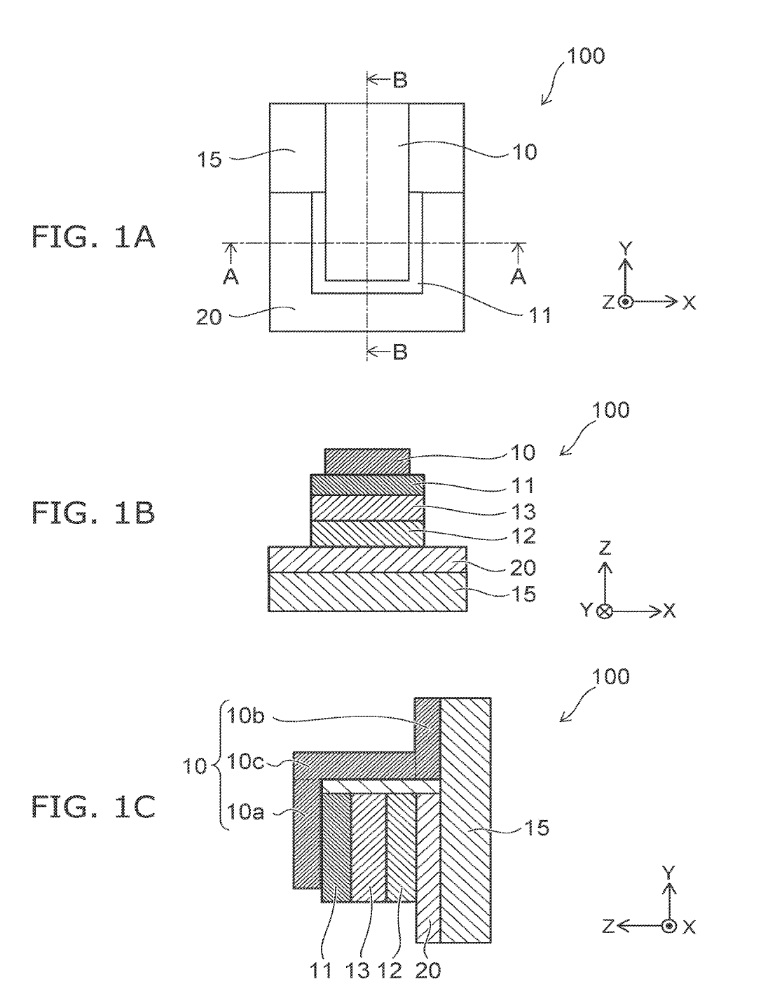

FIG. 1A to FIG. 1C are schematic views showing a photoelectric conversion element according to the embodiment.

FIG. 1A is a schematic plan view showing the photoelectric conversion element 100 according to the embodiment. FIG. 1B is a schematic cross-sectional view of the photoelectric conversion element 100 of cross-section A-A shown in FIG. 1A. FIG. 1C is a schematic cross-sectional view of the photoelectric conversion element 100 of cross-section B-B shown in FIG. 1A.

As shown in FIG. 1A to FIG. 1C, the photoelectric conversion element 100 includes a first electrode 10, a photoelectric conversion layer 13, and a first layer 11. The photoelectric conversion element 100 further includes a second layer 12, a second electrode 20, and a substrate 15. The photoelectric conversion element 100 is, for example, a solar cell or a sensor.

In this specification, a stacking direction from the photoelectric conversion layer 13 toward the first electrode 10 is taken as a Z-axis direction (a first direction). One direction perpendicular to the Z-axis direction is taken as an X-axis direction. A direction perpendicular to the X-axis direction and perpendicular to the Z-axis direction is taken as a Y-axis direction.

The second electrode 20 is provided on a portion of the substrate 15. The second electrode 20 is one selected from a positive electrode and a negative electrode.

The first electrode 10 is provided on the substrate 15 and is separated from the second electrode 20. The first electrode is the other of the positive electrode or the negative electrode.

As shown in FIG. 1C, the first electrode 10 includes a first portion 10a, a second portion 10b, and a third portion 10c. The first portion 10a is provided on the second electrode 20 and separated from the second electrode 20 in the Z-axis direction. For example, the first portion 10a is parallel to the second electrode 20. The second portion 10b is arranged with the second electrode 20 in the Y-axis direction. The third portion 10c is provided between the first portion 10a and the second portion 10b and is a portion that connects the first portion 10a to the second portion 10b.

The photoelectric conversion layer 13 is provided between the second electrode 20 and the first electrode 10 (the first portion 10a). The photoelectric conversion layer 13 includes a material having a perovskite structure.

The first layer 11 is provided between the first electrode (the first portion 10a) and the photoelectric conversion layer 13. The first layer 11 is a buffer layer (a first buffer layer). For example, the first layer 11 is nonhygroscopic and is a protective film that protects the photoelectric conversion layer 13 from moisture, etc.

The second layer 12 is provided between the second electrode 20 and the photoelectric conversion layer 13. The second layer 12 is a buffer layer (a second buffer layer).

In the photoelectric conversion element, one selected from the first layer 11 and the second layer 12 is a carrier transport layer (a hole transport layer) having hole transport properties; and the other of the first layer 11 or the second layer 12 is a carrier transport layer (an electron transport layer) having electron transport capabilities. In the example, the first layer 11 is a hole transport layer; and the second layer 12 is an electron transport layer.

For example, light is incident on the photoelectric conversion layer 13 via the substrate 15, the second electrode 20, and the second layer 12. Or, the light is incident on the photoelectric conversion layer 13 via the first electrode 10 and the first layer 11. At this time, electrons or holes are excited by the incident light in the photoelectric conversion layer 13.

The holes that are excited are extracted from the first electrode 10 via the first layer 11. Also, the electrons that are excited are extracted from the second electrode 20 via the second layer 12. Thus, electricity corresponding to the light incident on the photoelectric conversion element 100 is extracted via the first electrode 10 and the second electrode 20.

Members used in the photoelectric conversion element according to the embodiment will now be described in detail.

### Substrate 15

The substrate 15 supports the other components (the first electrode 10, the second electrode 20, the first layer 11, the second layer 12, and the photoelectric conversion layer 13). An electrode may be formed on the substrate 15. It is favorable for the substrate 15 not to be altered by heat or organic solvents. The substrate 15 is, for example, a substrate including an inorganic material, a plastic substrate, a polymer film, a metal substrate, etc. Alkali-free glass, quartz glass, etc., may be used as the inorganic material. Polyethylene, polyethylene terephthalate (PET), polyethylene naphthalate (PEN), polyimide, polyamide, polyamide-imide, a liquid crystal polymer, a cycloolefin polymer, etc., may be used as the materials of the plastic and polymer film. Stainless steel (SUS), titanium, silicon, etc., may be used as the material of the metal substrate.

In the case where the substrate 15 is disposed on the side of the photoelectric conversion element 100 where the light is incident, the substrate 15 includes a material (e.g., a transparent material) having a high light transmittance. In the case where the electrode (in the example, the first electrode 10) that is on the side opposite to the substrate 15 is transparent or semi-transparent, an opaque substrate may be used as the substrate 15. The thickness of the substrate 15 is not particularly limited as long as the substrate 15 has sufficient strength to support the other components.

In the case where the substrate 15 is disposed on the side of the photoelectric conversion element 100 where the light is incident, for example, an anti-reflection film having a moth-eye structure is mounted on the light incident surface. Thereby, the light is received efficiently; and it is possible to increase the energy conversion efficiency of the cell. The moth-eye structure is a structure including a regular protrusion array of about 100 nanometers (nm) in the surface. Due to the protrusion structure, the refractive index changes continuously in the thickness direction. Therefore, by interposing the anti-reflection film, a discontinuous change of the refractive index can be reduced. Thereby, the reflections of the light decrease; and the cell efficiency increases.

### First Electrode 10 and Second Electrode 20

In the following description relating to the first electrode and the second electrode 20, the light incident surface of the photoelectric conversion element 100 is positioned on the second electrode 20 side as viewed from the photoelectric conversion layer 13. However, in the embodiment, the light incident surface of the photoelectric conversion element 100 may be positioned on the first electrode 10 side.

The material of the second electrode 20 is not particularly limited as long as the material is conductive. A conductive material that is transparent or semi-transparent is used as the material of the electrode (in the example, the second electrode 20) on the side transmitting the light, A conductive metal oxide film, a semi-transparent metal thin film, etc., may be used as the electrode material that is transparent or semi-transparent.

Specifically, a conductive oxide film or a metal film including gold, platinum, silver, copper, or the like is used as the electrode that is transparent or semi-transparent. Indium oxide, zinc oxide, tin oxide, a complex of these substances such as indium-tin-oxide (ITO), fluorine-doped tin oxide (FTO), indium-zinc-oxide, etc., may be used as the conductive oxide film. It is particularly favorable for ITO or FTO to be used as the conductive oxide.

In the case where the material of the electrode is ITO, it is favorable for the thickness of the electrode to be not less than 30 nm and not more than 300 nm. In the case where the thickness of the electrode is thinner than 30 nm, the conductivity decreases; and the resistance becomes high. A high resistance may cause the photoelectric conversion efficiency to decrease. In the case where the thickness of the electrode is thicker than 300 nm, the flexibility of the ITO becomes low. Therefore, there are cases where the ITO breaks when stress is applied. It is favorable for the sheet resistance to be low; and it is favorable to be 10 Ω/□ or less. The first electrode 10 may be a single layer and may have a structure in which layers including materials having different work functions are stacked.

In the case where the electrode contacts the electron transport layer (the second layer 12), it is favorable for a material having a low work function to be used as the material of the electrode. For example, an alkaline metal, an alkaline earth metal, etc., may be used as a material having a low work function. Specifically, Li, In, Al, Ca, Mg, Sm, Tb, Yb, Zr, Na, K, Rb, Cs, Ba, or an alloy of these elements may be used.

The electrode that contacts the electron transport layer may include an alloy of at least one of the materials having low work functions described above and at least one selected from gold, silver, platinum, copper, manganese, titanium, cobalt, nickel, tungsten, and tin. Examples of the alloy include a lithium-aluminum alloy, a lithium-magnesium alloy, a lithium-indium alloy, a magnesium-silver alloy, a calcium-indium alloy, a magnesium-aluminum alloy, an indium-silver alloy, a calcium-aluminum alloy, etc., may be used. The electrode may be a single layer or may have a structure in which layers including materials having different work functions are stacked.

It is favorable for the thickness of the electrode contacting the electron transport layer to be not less than 1 nm and not more than 500 nm. It is more favorable for the thickness of the electrode to be not less than 10 nm and not more than 300 nm. In the case where the thickness of the electrode is thinner than 1 nm, the resistance becomes too high; and the charge that is generated cannot be conducted sufficiently to the external circuit. In the case where the thickness of the electrode is thicker than 500 nm, a long period of time is necessary for the formation of the electrode. Therefore, the material temperature increases; and there are cases where the other materials are damaged and the performance degrades. Because a large amount of material is used, the time occupied by the apparatus (the film formation apparatus) that forms the electrode lengthens which may increase the cost.

The first electrode 10 includes PEDOT (polyethylene dioxythiophene). A polythiophene polymer is used as the material of the first electrode 10. For example, Clevios PH 500, Clevios PH, Clevios PV P Al 4083, and Clevios HIL1,1 made by H. C. Starck and the like may be used as the polythiophene polymer. The thickness of the first electrode 10 is not less than 10 nm and not more than 10 millimeters (mm).

The work function of PEDOT is 4.4 eV. The work function of the first electrode 10 can be adjusted by mixing another type of material into PEDOT. For example, the work function can be adjusted to a range of 5.0 to 5.8 eV by mixing P55 (styrenesulfonate) into PEDOT.

### Photoelectric Conversion Layer 13

The photoelectric conversion layer 13 may include a material having a perovskite structure. The perovskite structure includes, for example, an ion A1, an ion A2, and an ion X. The perovskite structure can be expressed as A1A2X₃. The structure may be a perovskite structure when the ion A2 is smaller than the ion A1. For example, the perovskite structure has a cubic unit lattice. The ion A1 is disposed at each corner of the cubic crystal; and the ion A2 is disposed at the body center. The ion X is disposed at each face center of the cubic crystal centered around the ion A2 at the body center.

The orientation of the A2X₆ octahedron distorts easily due to interactions with the ions A1. Due to the decrease of the symmetry, a Mott transition occurs; and valence electrons localizing at the ions NI can spread as a band. It is favorable for the ion A1 to be CH₃NH₃. It is favorable for the ion A2 to be at least one selected from Pb and Sn. It is favorable for the ion X to be at least one selected from Cl, Br, and I. Each of the materials included in the ion A1, the ion A2, and the ion X may be a single material or a mixed material.

### First Layer 11 and Second Layer 12

As described above, in the example, the first layer 11 is a hole transport layer; and the second layer 12 is an electron transport layer. In the embodiment, the hole transport layer is disposed between the photoelectric conversion layer 13 and the electrode including PEDOT. In other words, the first layer 11 is disposed between the first electrode 10 and the photoelectric conversion layer 13.

The hole transport layer is a material that receives holes from the active layer (the photoelectric conversion layer 13). The material of the hole transport layer is not constrained as long as the material has hole transport properties. The electron transport layer is a material that receives electrons from the active layer. The material of the electron transport layer is not constrained as long as the material has electron transport capabilities.

### Electron Transport Layer

The electron transport layer includes at least one selected from a halogen compound and a metal oxide.

LiF, LID, LiBr, LiI, NaF, NaCl, NaBr, NaI, KF, KCl, KBr, KI, and CsF are favorable examples of the halogen compound. It is more favorable to use LiF as the halogen compound used in the electron transport layer.

Titanium oxide, molybdenum oxide, vanadium oxide, zinc oxide, nickel oxide, lithium oxide, calcium oxide, cesium oxide, and aluminum oxide are favorable examples of the metal oxide. For example, amorphous titanium oxide obtained by hydrolysis of titanium alkoxide by a sol-gel method may be used.

Metal calcium or the like is a favorable material in the case where an inorganic substance is used.

In the case where titanium oxide is used as the material of the electron transport layer, it is favorable for the thickness of the electron transport layer to be not less than 5 nm and not more than 20 nm. In the case where the electron transport layer is too thin, because the hole blocking effect undesirably decreases, the excitons that are generated undesirably deactivate before dissociating into electrons and holes; and a current cannot be extracted efficiently. In the case where the electron transport layer is too thick, the film resistance becomes large; and the light conversion efficiency decreases because the generated current is limited.

### Hole Transport Layer

The hole transport layer includes, for example, a nonhygroscopic material. The hygroscopicity of the hole transport layer is lower than the hygroscopicity of the photoelectric conversion layer 13.

The hygroscopicity of the photoelectric conversion layer 13 and the hygroscopicity of the first layer 11 can be compared by the following method.

For example, the sealant of the photoelectric conversion element is removed; and the moisture concentration included in the first layer 11 and the photoelectric conversion layer 13 is analyzed after placing the photoelectric conversion element in an atmosphere of 85% humidity at 85° C. for 1000 hours. Thereby, the hygroscopicity can be compared. For example, elemental mapping using a transmission electron microscope (TEM), time-of-flight secondary ion mass spectrometry (time-of-flight secondary ion mass spectrometer (TOF-SIMS)), Auger electron spectrometry, TG-MS, DSC, etc., can be used to analyze each layer. The evaluation method of the hygroscopicity is not constrained as long as the method can perform a relative comparison of the moisture absorption amount of each layer.

A p-type organic semiconductor may be used as the material of the hole transport layer. The p-type organic semiconductor includes, for example, a copolymer including a donor unit and an acceptor unit.

For example, it is favorable for the copolymer including the donor unit and the acceptor unit to be used as the material of the hole transport layer. It is possible to arbitrarily design the HOMO energy level using the intramolecular interactions. Fluorene, thiophene, etc., may be used as the donor unit. Benzothiadiazole, etc., may be used as the acceptor unit. The characteristics of the copolymer are dependent on the balance between the electron-accepting property and the electron-donating property of the units that are substantially copolymerized. Polythiophene and a derivative of polythiophene, polypyrrole and a derivative of polypyrrole, a pyrazoline derivative, an arylamine derivative, a stilbene derivative, a triphenyldiamine derivative, oligothiophene and a derivative of oligothiophene, polyvinyl carbazole and a derivative of polyvinyl carbazole, polysilane and a derivative of polysilane, a polysiloxane derivative including an aromatic amine at a side chain or a main chain, polyaniline and a derivative of polyaniline, a phthalocyanine derivative, porphyrin and a derivative of porphyrin, polyphenylene vinylene and a derivative of polyphenylene vinylene, polythienylene vinylene and a derivative of polythienylene vinylene, a benzodithiophene derivative, a thieno[3,2-b]thiophene derivative, etc., may be used as the material of the hole transport layer. These materials also may be used in the hole transport layer. Also, a copolymer of the materials recited above may be used as the material of the hole transport layer. As the copolymer, for example, a thiophene-fluorene copolymer, a phenylene ethynylene-phenylene vinylene copolymer, etc., may be used. In the hole transport layer using these materials, the hygroscopicity is low; and pinholes do not occur easily.

Favorably, the material of the hole transport layer is polythiophene or a derivative of polythiophene, which is a pi-conjugated conductive polymer. Polythiophene and derivatives of polythiophene have excellent stereoregularity. The solubility in a solvent of polythiophene and derivatives of polythiophene is relatively high.

The polythiophene and the derivative of polythiophene are not particularly limited as long as a compound including a thiophene skeleton is used. Polyalkylthiophene, polyarylthiophene, polyalkyl isothionaphthene, polyethylene dioxythiophene, etc., are specific examples of the polythiophene and the derivative of polythiophene. Poly(3-methylthiophene), poly(3-butylthiophene), poly(3-hexylthiophene), poly(3-octylthiophene), poly(3-decylthiophene), poly(3-dodecylthiophene), etc., may be used as polyalkylthiophene. Poly(3-phenylthiophene), poly(3-(p-alkylphenylthiophene)), etc., may be used as polyarylthiophene. Poly(3-butyl isothionaphthene), poly(3-hexyl isothionaphthene), poly(3-octyl isothionaphthene), poly(3-decyl isothionaphthene), etc., may be used as polyalkyl isothionaphthene.

The hole transport layer can be formed by dissolving the materials recited above in a solvent and coating the solution. For example, an unsaturated hydrocarbon solvent, a halogenated aromatic hydrocarbon solvent, a halgenated saturated hydrocarbon solvent, and an ether may be used as the solvent. Toluene, xylene, tetralin, decalin, mesitylene, n-butylbenzene, sec-butylbenzene, tert-butylbenzene, etc., may be used as the unsaturated hydrocarbon solvent. Chlorobenzene, dichlorobenzene, trichlorobenzene, etc., may be used as the halogenated aromatic hydrocarbon solvent. Carbon tetrachloride, chloroform, dichloromethane, dichloroethane, chlorobutane, bromobutane, chloropentane, chlorohexane, bromohexane, chlorocyclohexane, etc., may be used as the halgenated saturated hydrocarbon solvent. Tetrahydrofuran, tetrahydropyran, etc., may be used as the ether. A halogen aromatic solvent is particularly favorable as the solvent. It is possible to use these solvents independently or as a mixture.

As the material of the hole transport layer, a derivative of PCDTBT (poly[N-9″-hepta-decanyl-2,7-carbazole-alt-5,5-(4′,7′-di-2-thienyl-2′,1′3′-benzothiadiazole)]), etc., which is a copolymer including carbazole, benzothiadiazole, and thiophene may be used. Further, a copolymer of a benzodithiophene (BDT) derivative and a thieno[3,2-b]thiophene derivative is favorable. For example, poly[[4,8-bis[(2-ethylhexyl)oxy]benzo[1,2-b: 4,5-bldithiophene-2,6-diyl][3-fluoro-2-[(2-ethylhexyl)carbonyl]thieno[3,4-b]thiophenediyl]] (PTB7), PTB7-Th (having the alternative names of PCE10 and PBDTTT-EFT) to which a thienyl group having electron-donating properties weaker than those of the alkoxy group of PTB7 is introduced, or the like is favorable.

The hole transport layer in which these materials are used has low hygroscopicity; and pinholes do not occur easily. The hole transport layer in which the materials recited above are used has excellent durability particularly at or below the glass transition temperature.

A metal oxide also may be used as the material of the hole transport layer. Titanium oxide, molybdenum oxide, vanadium oxide, zinc oxide, nickel oxide, lithium oxide, calcium oxide, cesium oxide, and aluminum oxide may be used as a favorable example of the metal oxide. These materials have low hygroscopicity; and, for example, these materials themselves do not undergo photodecomposition. Also, these materials are inexpensive.

Thiocyanate may be used as the material of the hole transport layer. Thiocyanate is a compound that includes a conjugate base of thiocyanic acid. An alkaline metal, an alkaline earth metal, copper, silver, mercury, lead, etc., may be used as a metal forming a salt. Mixtures of these substances may be used. It is favorable for the thiocyanate to be copper thiocyanate. These materials have low hygroscopicity; and, for example, these materials themselves do not undergo photodecomposition. Because these materials have low catalytic activity, these materials do not decompose organic materials. Also, these materials are inexpensive.

It is favorable for the energy level of the highest occupied molecular orbital energy level (the HOMO energy level) of the hole transport layer to be positioned between the work function of the electrode including PEDOT and the valence band of the photoelectric conversion layer 13 including the material having the perovskite structure. In other words, the absolute value of the difference between the HOMO energy level and the vacuum level of the p-type organic semiconductor included in the hole transport layer is a value between the work function of the first electrode 10 and the absolute value of the difference between the valence band and the vacuum level of the photoelectric conversion layer 13. Thereby, the hole transport layer can transport holes efficiently. The HOMO energy level of the hole transport layer is, for example, not less than 4 eV and not more than 6 eV. The work function, the HOMO energy level, and the energy level of the valence band can be measured by, for example, photoelectron spectroscopy.

The thickness of the hole transport layer is not less than 2 nm and not more than 300 nm. In the case where the hole transport layer is thinner than 2 nm, a voltage drop due to film formation defects or the like occurs. In the case where the hole transport layer is thicker than 300 nm, the electrical resistance becomes large; and the conversion efficiency decreases.

For example, a photoelectric conversion element 190 of a reference example may be considered in which the first layer 11 (the hole transport layer) of the photoelectric conversion element 100 is omitted. In the photoelectric conversion element 190, the first electrode 10 is provided directly on the photoelectric conversion layer 13 (the perovskite layer). Other than the first layer 11 not being included, the configuration of the photoelectric conversion element 190 is similar to that of the photoelectric conversion element 100.

The crystal structure of the material that has the perovskite structure used in the photoelectric conversion layer changes easily (breaks down easily) due to moisture. Therefore, when the electrode is formed on the photoelectric conversion layer, the perovskite structure may change due to the moisture included in the material; and the characteristics of the photoelectric conversion element may degrade. Thereby, the manufacturing fluctuation may become large; and the characteristics may become unstable. Even when using the photoelectric conversion element 190, the perovskite structure may change due to moisture in the atmosphere; and the characteristics may become unstable.

As another reference example, for example, a photoelectric conversion element 191 may be considered in which a layer that includes Spiro-OMeTAD (2,2′,7,7′-tetrakis-(N,N-di-4-methoxyphenylamino)-9,9′-spirobifluorene) is used as the hole transport layer. Other than the configuration of the material used in the hole transport layer, the photoelectric conversion element 191 is similar to the photoelectric conversion element 100.

As a dopant of the hole transport layer of the photoelectric conversion element 191 of the reference example, 4-tert-butylpyridine (tBP), lithium-bis(trifluoromethanesulfonyl)imide (Li-TFSI), acetonitrile, or the like is doped. For example, to form the hole transport layer of the photoelectric conversion element 191, a coating liquid is used in which 28.5 μL of tBP and 17.5 μL of a Li-TFSI solution (520 mg of Li-TFSI in 1 ml of acetonitrile) are added to a chlorobenzene solution including 80 mg/ml of Spiro-OMeTAD.

For example, Li-TFSI is hygroscopic. Therefore, in the case where moisture exists when manufacturing, the carrier transport capability of the hole transport layer may be lost. Thereby, the manufacturing fluctuation becomes large; and the characteristics become unstable. Even when using the photoelectric conversion element 191, the carrier transport capability may be lost due to moisture in the atmosphere; and the characteristics may become unstable.

Also, there are cases where the perovskite structure of the photoelectric conversion element 191 changes due to the dopant included in the hole transport layer.

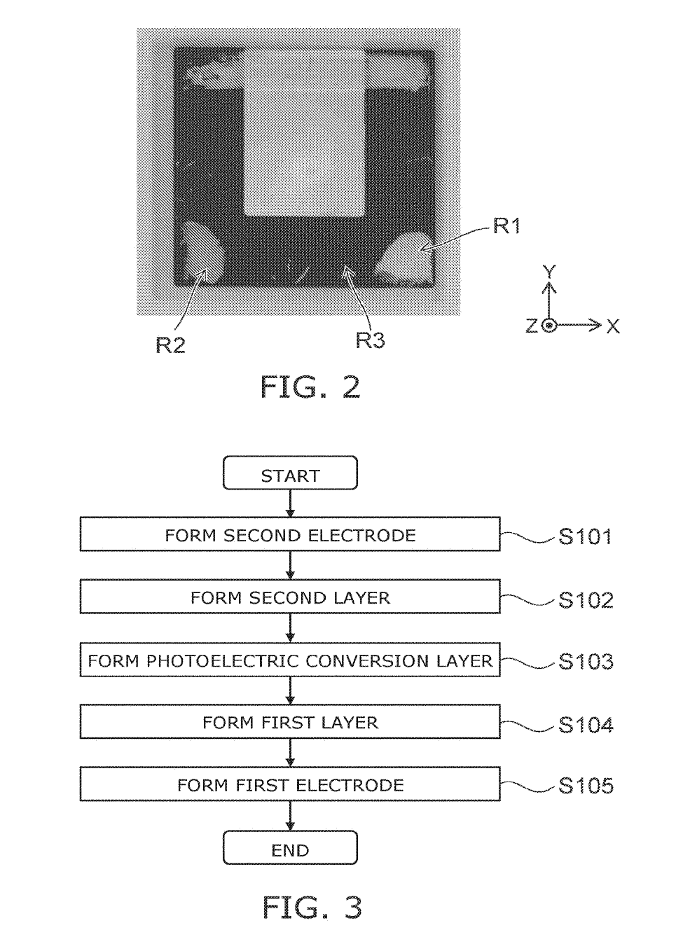

FIG. 2 is a photograph showing the photoelectric conversion element of the reference example. Region R1 shown in FIG. 2 is a region where tBP is dropped onto the perovskite layer which is the photoelectric conversion layer. Region R2 is a region where acetonitrile is dropped onto the perovskite layer. The color of region R1 and the color of region R2 where the dopants of the hole transport layer are dropped are different from the color of region R3 where a dopant is not dropped. This is because the dopants that are dropped dissolve the perovskite layer. Thus, in the photoelectric conversion element 191, the perovskite structure changes due to the material used in the hole transport layer. It is considered that this causes the characteristics of the photoelectric conversion element to degrade and become unstable.

For example, the durability of the photoelectric conversion element can be evaluated according to JIS C 8938 B-1. In the endurance test, the temperature of the photoelectric conversion element is maintained at a high temperature; and the temporal change of the photoelectric conversion efficiency is measured. It can be seen from the evaluations of the photoelectric conversion element 190 of the reference example or the durability of the photoelectric conversion element 191 that the performance after 1000 hours decreases to about 10% of the initial performance.

Conversely, it can be seen from the evaluation according to JIS C 8938 B-1 of the durability of the photoelectric conversion element 100 according to the embodiment that the performance after 1000 hours is maintained at not less than 90% of the initial performance.

The hygroscopicity of the hole transport layer of the photoelectric conversion element 100 according to the embodiment is lower than the hygroscopicity of the hole transport layer of the photoelectric conversion element 191 of the reference example. In the photoelectric conversion element 100, the first layer 11 (the hole transport layer) is, for example, nonhygroscopic. Therefore, the carrier transport capability of the first layer 11 does not degrade easily due to moisture.

Also, the hygroscopicity of the hole transport layer of the photoelectric conversion element 100 according to the embodiment is lower than the hygroscopicity of the photoelectric conversion layer 13. The hole transport layer of the photoelectric conversion element 100 is stacked as a protective film of the photoelectric conversion layer 13. Thereby, when manufacturing and when using, the change of the perovskite structure of the photoelectric conversion layer 13 due to moisture can be suppressed. According to the embodiment, the manufacturing fluctuation and the durability (the reliability) can be improved; and stable characteristics can be obtained.

### Second Embodiment

A second embodiment relates to a method for manufacturing the photoelectric conversion element 100.

FIG. 3 is a flowchart showing the method for manufacturing the photoelectric conversion element according to the second embodiment. The method for manufacturing the photoelectric conversion element 100 according to the embodiment includes step S101 to step S105.

The substrate 15 includes a glass substrate in the example. First, the second electrode 20 is formed on the glass substrate (step S101). The second electrode 20 is formed by coating. For example, a film of FT© is formed as the second electrode 20. To form the second electrode 20, it is also possible to use a method that can form a thin film such as vacuum vapor deposition, sputtering, ion plating, plating, etc.

The second layer 12 is formed on the second electrode (step S102). A coating method such as spin coating or the like is used to form the second electrode 20. It is favorable for the solution that is coated to be pre-filtered using a filter. After coating the solution to have the desired thickness, heating and drying is performed using a hotplate, etc. It is favorable to perform the heating and the drying at a temperature of not less than 50° C. and not more than 100° C. for about 1 minute to about 10 minutes. The heating and the drying are performed while promoting hydrolysis inside air.

For example, a thin film of titanium oxide is formed as the second layer 12. In this case, the second layer 12 is formed by multiply coating a titanium di-isopropoxide-bis(acetylacetonate) solution by spin coating. Subsequently, baking is performed at 400° C. The method for forming the second layer 12 also may include other methods that can form thin films.

The photoelectric conversion layer 13 is formed on the second layer 12 (step S103). The photoelectric conversion layer 13 is formed by a coating method such as spin coating, etc. For example, the photoelectric conversion layer 13 is formed by coating a DMF (N,N-dimethylformamide) solution including methylammonium iodide and lead iodide in a nitrogen atmosphere by spin coating. For example, the substance amount (moles) of the methylammonium iodide is equal to the substance amount of the lead iodide in the DMF solution. Subsequently, annealing is performed at 90° C. for 3 hours.

Subsequently, the first layer 11 is formed on the photoelectric conversion layer 13 (step S104). A coating method is used to form the first layer 11. For example, spin coating, dip coating, casting, bar-coating, roll-coating, wire-bar coating, spraying, screen printing, gravure printing, flexographic printing, offset printing, gravure-offset printing, dispenser-coating, nozzle-coating, capillary-coating, inkjet, etc., may be used as the coating method. These coating methods may be used independently or in combination. For example, the first layer 11 is formed by using spin coating to coat a solution in which PCE-10 (poly[4,8-bis(5-(2-ethylhexyl)thiophen-2-yl)benzo[1,2-b; 4,5-131dithiophene-2,6-diyl-alt-(4-(2-ethylhexyl)-3-fluorothieno[3,4-b]thiophene-)-2-carboxylate-2-6-diyl)] made by 1-Material Co., Ltd.) is dissolved in chlorobenzene.

Subsequently, the first electrode 10 is formed on the first layer 11 (step S105). A coating method such as spin coating, etc., may be used to form the first electrode 10.

It is favorable for the coating liquid that is coated in the formation of the first electrode 10 to be an ethanol aqueous solution including the material (a first material) of the first electrode 10. The concentration of the ethanol in the ethanol aqueous solution is, for example, not less than 3 wt % (weight percent) and not more than 70 wt %. Thereby, the surface tension and permeation of the solution can be adjusted; and permeation into the photoelectric conversion layer 13 via the first layer 11 can be suppressed. The first material of the first electrode 10 includes, for example, a polythiophene conductive polymer. For example, after coating an ethanol aqueous solution in which PEDOT is dispersed to have the desired thickness, heating and drying are performed using a hotplate, etc. The heating and the drying is performed at a temperature of not less than 140° C. and not more than 200° C. for about 1 minute to about 10 minutes. Or, the drying is performed at 120° C. after coating SEPLEGYDA OC-AE (made by Shin-Etsu Polymer Co., Ltd.). It is favorable for the solution that is coated to be pre-filtered using a filter.

The method for forming the first electrode 10 is not particularly limited as long as the method can form a thin film. The first material of the first electrode 10 may include a conductive substance that can be dispersed in water such as silver nanoparticles, gold nanoparticles, etc.

As described above, the photoelectric conversion element 100 according to the embodiment is manufactured.

In the photoelectric conversion element 190 of the reference example described above, the first electrode 10 is provided directly on the photoelectric conversion layer 13. Then, for example, the first electrode 10 is formed by coating a solution in which PEDOT is dispersed in water. The coatability of the solution degrades because the structure of the material having the perovskite structure used in the photoelectric conversion layer is changed easily by moisture. Therefore, the manufacturing fluctuation becomes large. The conversion efficiency decreases due to the change of the perovskite structure.

For example, in the photoelectric conversion element 191 of the reference example described above, a solution in which PEDOT is dispersed in water is coated onto a hole transport layer including Spiro-OMeTAD. Here, the hole transport layer includes a dopant that is hygroscopic. Therefore, in the photoelectric conversion element 191 as well, the coatability of the solution degrades. Due to the moisture, the carrier transport capability of the hole transport layer is lost; and the conversion efficiency decreases.

Conversely, in the manufacture of the photoelectric conversion element 100 according to the embodiment, for example, the coating liquid that is used to form the first electrode 10 is coated onto the nonhygroscopic first layer 11. Thereby, even in the case where the coating liquid includes moisture, the decrease of the coatability can be suppressed. The decrease of the carrier transport capability of the first layer 11 due to moisture can be suppressed. The first layer 11 is a film that protects the photoelectric conversion layer 13. Thereby, the decrease of the efficiency of the photoelectric conversion can be suppressed.

In the manufacture of the photoelectric conversion element 100 according to the embodiment, the first electrode 10, the second electrode 20, the first layer 11, the second layer 12, and the photoelectric conversion layer 13 can be formed by coating on a substrate. Thus, by manufacturing the photoelectric conversion element by coating, the manufacturing cost of the device can be low.

According to the embodiment, the stability of the characteristics of a photoelectric conversion element formed by coating on a substrate can be improved.

According to the embodiments, a photoelectric conversion element and a method for manufacturing the photoelectric conversion element can be provided in which the stability of the characteristics can be improved.

In this specification, “perpendicular” and “parallel” include not only strictly perpendicular and strictly parallel but also, for example, the fluctuation due to manufacturing processes, etc.; and it is sufficient to be substantially perpendicular and substantially parallel.

Hereinabove, embodiments of the invention are described with reference to specific examples. However, the embodiments of the invention are not limited to these specific examples. For example, one skilled in the art may similarly practice the invention by appropriately selecting specific configurations of components of the photoelectric conversion layer, the first electrode, the second electrode, the first layer, the second layer, etc., from known art; and such practice is within the scope of the invention to the extent that similar effects can be obtained.

Any two or more components of the specific examples may be combined within the extent of technical feasibility and are within the scope of the invention to the extent that the spirit of the invention is included.

All photoelectric conversion elements and methods for manufacturing photoelectric conversion elements practicable by an appropriate design modification by one skilled in the art based on the photoelectric conversion element and the method for manufacturing the photoelectric conversion element described above as embodiments of the invention are within the scope of the invention to the extent that the spirit of the invention is included.

Various modifications and alterations within the spirit of the invention will be readily apparent to those skilled in the art; and all such modifications and alterations should be seen as being within the scope of the invention.

Although several embodiments of the invention are described, these embodiments are presented as examples and are not intended to limit the scope of the invention. These novel embodiments may be implemented in other various forms; and various omissions, substitutions, and modifications can be performed without departing from the spirit of the invention. Such embodiments and their modifications are within the scope and spirit of the invention and are included in the invention described in the claims and their equivalents.

What is claimed is:

1. A method for manufacturing a photoelectric conversion element, the element including a substrate, a photoelectric conversion layer, a first electrode, a second electrode, a first layer, and a second layer, the photoelectric conversion layer being provided between the substrate and the first electrode, the photoelectric conversion layer including a material having a perovskite structure, the first layer being provided between the photoelectric conversion layer and the first electrode and having hole transport properties, the second layer being provided between the substrate and photoelectric conversion layer, the second electrode being provided between the substrate and the second layer, a hygroscopicity of the first layer being lower than a hygroscopicity of the photoelectric conversion layer, the method comprising:
forming the first layer by coating a coating liquid on the photoelectric conversion layer, the photoelectric conversion layer being included in a structural body, the structural body including the substrate, the second electrode, the second layer and the photoelectric conversion layer; and
forming the first electrode by coating a solution including a first material on the first layer, the first material including at least one selected from the group consisting of polythiophene and a conductive substance.

2. The method according to claim 1, wherein the first material includes the polyethylene dioxythiophene.

3. The method according to claim 1, wherein the first layer includes a p-type organic semiconductor.

4. The method according to claim 1, wherein the first layer includes a metal oxide.

5. The method according to claim 1, wherein the first layer includes thiocyanate.

6. The method according to claim 1, wherein the material having the perovskite structure is A1A2X₃,
the A1 including CH₃NH₃,
the A2 including at least one of Pb or Sn,
the X including at least one of Cl, Br, or I.

7. The method according to claim 1, wherein the solution further includes an aqueous solution.

8. The method according to claim 7, wherein the aqueous solution further includes ethanol.
